(19) United States
(12) Patent Application Publication
(10) Pub. No.: US 2025/0350247 A1
(43) Pub. Date: Nov. 13, 2025

(54) HIGH-TRANSCONDUCTANCE INPUT STAGE FOR COMPARATORS AND AMPLIFIERS

(71) Applicant: Analog Devices, Inc., Wilmington, MA (US)

(72) Inventors: Devrim Yilmaz Aksin, Stokesdale, NC (US); Gonenc Berkol, Istanbul (TR); Reha Kepenek, Ankara (TR); Brian D. Hamilton, Menlo Park, CA (US)

(21) Appl. No.: 18/660,025

(22) Filed: May 9, 2024

(51) Int. Cl. H03F 1/42; H03F 3/45; H03G 3/30

(52) U.S. Cl. CPC H03F 1/42; H03F 3/45197; H03G 3/30; H03F 2200/36; H03G 2201/103

(57) ABSTRACT

A low input capacitance input stage for a high voltage amplifier includes a first input transistor configured to receive a first portion of a differential input signal and provide a first portion of an output signal, and a second input transistor configured to receive a second portion of the differential input signal and provide a second portion of the output signal. The amplifier can include a degeneration stage with a bias generator circuit. The degeneration stage can include first and second degeneration transistors coupled in series. The bias generator circuit can provide respective first and second bias signals to gate terminals of the first and second degeneration transistors to control an impedance of a signal path that couples source terminals of the first and second input transistors.

### BACKGROUND

A transconductance circuit (also referred to as a “transconductor” or a “voltage-to-current converter”) is a circuit that generates an output current corresponding to, or proportional to, an input voltage. Transconductance circuits may be used in many modern electronic systems in a wide range of markets, such as including industrial, military, automotive, and automatic testing (e.g., pin electronics) environments. In an example, one or more transconductance circuits may be used in an amplifier or a comparator circuit.

### BRIEF SUMMARY

The present inventors have recognized that a problem to be solved includes providing an input stage for a comparator or amplifier, where the input stage has high transconductance, large differential voltage compliance and reliability, and high bandwidth characteristics. The input stage can have a relatively low input capacitance characteristic. The input stage can optionally be used as an interface for a comparator or other automated test equipment.

In an example, a solution can include or use a system comprising a transconductance circuit with degeneration transistors. In some examples, a transconductance circuit with degeneration transistors can be used as a transconductance input stage of an amplification stage, where the transconductance input stage is configured to convert an input voltage signal to an output current signal. In some examples, the amplification stage may further include a load stage, configured to convert the input stage output current back to an output voltage. One or more of such amplification stages may be included in a device such as an amplifier or a comparator.

In an example, an input stage circuit can include a first input transistor (M_{P}) configured to receive a first portion of a differential input signal at a first gate terminal (V_{IP}) and provide a first portion of an output signal at a first drain terminal (I_{OP}) of the first input transistor, and the input stage circuit can include a second input transistor (M_{N}) configured to receive a second portion of the differential input signal at a second gate terminal (V_{IM}) and provide a second portion of the output signal at a second drain terminal (I_{OM}) of the second input transistor. The input stage circuit can further include a degeneration stage circuit with first and second degeneration transistors (M_{DP}, M_{DM}) coupled in series and a bias generator circuit. The bias generator circuit can be configured to provide respective first and second bias signals to gate terminals of the first and second degeneration transistors to control an impedance of a signal path that couples source terminals of the first and second input transistors.

In an example, a method for controlling gain and bandwidth characteristics of an input stage circuit can include receiving first and second input stage input signals at respective first and second input nodes of respective first and second input transistors, using a first bias circuit, providing a first bias signal to a gate terminal of a first degeneration transistor and a source terminal of the first input transistor, using a second bias circuit, providing a second bias signal to a gate terminal of a second degeneration transistor and an source terminal of the second input transistor, and in response to receiving the first and second bias signals at the first and second degeneration transistors, adjusting an impedance characteristic of a signal path coupling the first and second input transistors, providing a first input stage output signal using a first output terminal of the first input transistor, and providing a second input stage output signal using a second output terminal of the second input transistor.

This summary is not intended to provide an exclusive or exhaustive explanation of the invention. The detailed description is included to provide further information about the present patent application.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates generally an example of a first test system that includes a pin driver.

FIG. 2 illustrates generally an example of a multiple-stage comparator circuit.

FIG. 3 illustrates generally an example of a first transconductance circuit.

FIG. 4 illustrates generally an example of a second transconductance circuit.

FIG. 5 illustrates generally an example of a first example transconductance stage of an amplifier.

FIG. 6 illustrates generally an example of a second example transconductance stage of an amplifier.

FIG. 7 illustrates generally an example of a third example transconductance stage of an amplifier.

FIG. 8 illustrates generally an example of a fourth example transconductance stage of an amplifier.

FIG. 9 illustrates generally an example of a method for controlling gain and bandwidth characteristics of an input stage circuit.

### DETAILED DESCRIPTION

High-voltage comparators or amplifiers are key components in many modern electronic systems. Such amplifiers are applied in industrial, medical, automotive, and automatic testing equipment (ATE) devices, among others. The particular end application can have various requirements, such as for particular voltage compliance levels, and therefore various amplifier systems are needed, such as systems that can operate over a wide input/output voltage range, including in a range that may exceed a breakdown voltage of individual devices that comprise such amplifier systems.

In an example, ATE applications use high-voltage amplifiers to provide a time management unit (TMU) and/or a high-voltage driver (HVD), where wide input/output voltage range (e.g., hundreds of volts), relatively high-speed (e.g., tens of megahertz) and low-power consumption (e.g., in a milliwatt range, to enable high volume device testing) are three key performance metrics. A source impedance, e.g., of a preceding stage that drives the amplifier, can also affect the bandwidth characteristics of the system. In case of applications where a source impedance is high, subsequent amplifier stages can be configured to have a characteristically low input capacitance to ensure adequate bandwidth performance. Additionally, when an amplifier is used in feedback configuration, e.g., to achieve the maximum possible bandwidth at a minimum power consumption, a low-capacitance input stage can be desired.

In an example, laterally diffused MOSFET (LDMOS) devices can be used in high voltage amplifier input stages. Such devices can have a characteristically high blocking voltage due to a diffused p-type channel region in a low-doped n-type drain region. Due to the relatively large size of such devices, the devices can have characteristically higher parasitic capacitance values compared to that of other, non-LDMOS or low-voltage devices.

The present inventors have recognized that a problem to be solved includes providing an input stage, or transconductance stage, that has low input capacitance, large differential voltage compliance, and high bandwidth characteristics. The problem includes providing a differential input stage that has high tolerance for large Common Mode (CM) and Differential Mode (DM) input voltages. The present inventors have recognized that an issue with a standard differential pair input stage, such as can use DMOS devices (e.g., double-diffused MOSFET devices), is that while a differential pair can handle a large CM range, such an input stage can be limited by a relatively low (e.g., 5V) Vgs (gate-source voltage) limit, beyond which the device gate oxide can fail and device damage can occur. This limitation means that while a DMOS device can tolerate high Vds (drain-source voltage) and Vdg (drain-gate voltage), the Vgs tolerance is low, resulting in a circuit that can handle high CM voltages but has small DM voltage tolerance. Furthermore, the present inventors have recognized that using high voltage diodes at the tail node (e.g., provided in series with the sources of the DMOS devices that comprise a differential pair) to improve DM tolerance is not always available because not all processes offer high voltage diodes. Furthermore, even if high voltage diodes are available, they can have characteristically slow reverse recovery time characteristics, which can inhibit their use in high speed circuits such as comparators.

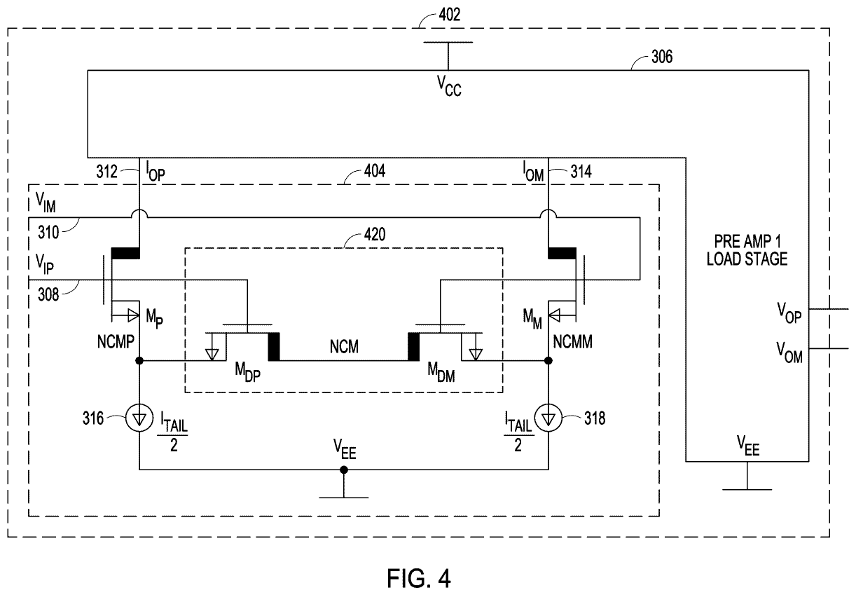

Other solutions that employ transistors at the tail node (e.g., in series with the differential pair device sources; see FIG. 4) to achieve high CM and DM voltage tolerance can result in relatively poor performance in terms of gain and bandwidth. Specifically, in a particular transistor-based approach, physically large transistors are used to achieve high gain, which in turn capacitively loads the amplifier inputs and reduces the bandwidth of the input stage. Achieving high bandwidth generally requires physically small transistors which in turn reduces the gain. The present inventors have recognized that a solution to these problems and limitations can include or use a bias generator circuit to control transistors at the tail node. By controlling operation of these transistors, CM and DM voltage tolerance is improved, and high gain and high bandwidth can be achieved.

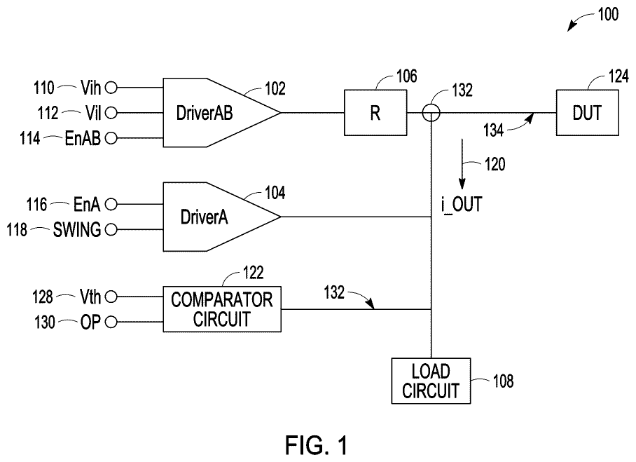

FIG. 1 illustrates generally a first example test system 100 showing a test system topology that includes multiple driver stages, a load, and a comparator stage. The first example test system 100 includes a driver system comprising a first DriverAB 102 that can include a class AB driver circuit, and a first DriverA 104 that can include a class A driver circuit. The first example test system 100 can further include an output element such as a first resistor 106 that can be configured to provide a specified output or load impedance. In an example, the first example test system 100 includes a comparator circuit 122, or a first load circuit 108, such as can include an active load or other loading device. In an example, the test system is configured to provide a first output current 120, i_OUT, at a DUT interface or DUT node 132. The DUT node 132 can be coupled to a DUT 124 using a loaded signal path 134. In some examples, the first resistor 106 and the loaded signal path 134 have matching impedance characteristics.

In an example, the first DriverAB 102 can be configured to produce a voltage stimulus signal by selecting between parallel-connected diode bridges with each bridge driven by a unique, dedicated DC voltage level. In the first example test system 100 of FIG. 1, DC voltages Vih 110 and Vil 112 drive diode bridges in the first DriverAB 102. The switching stage can be followed by a voltage buffering stage that can provide power gain, such as can be used to produce large currents to serve a 50 ohm DUT environment.

In contrast with the first DriverAB 102, the first DriverA 104 can be configured to produce transitions at the DUT node 132 using a relatively large current switch stage that can be coupled directly to the DUT node 132. A current switching stage in the first DriverA 104 can alternately switch current into and out of the DUT node 132 in response to a control signal Swing 118, such as can be a voltage control signal.

FIG. 1 includes the comparator circuit 122. The comparator circuit 122 can include a single-stage or multiple-stage comparator that is configured to receive a signal from the DUT 124, such as via the DUT node 132 and the loaded signal path 134. The comparator circuit 122 can compare the received signals to a comparator reference signal 128 (e.g., Vth) and, in response, provide a differential comparator output signal 130 (e.g., OP).

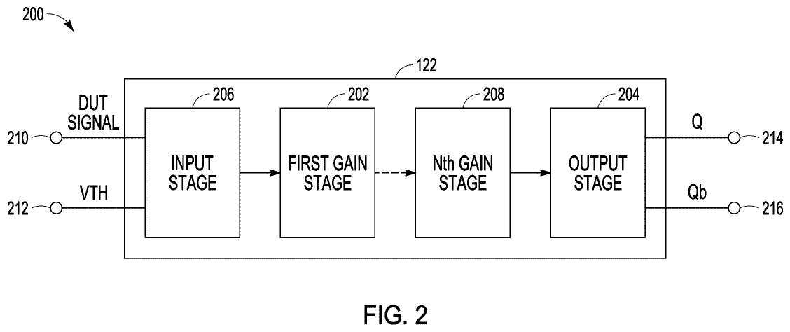

FIG. 2 illustrates generally a comparator example 200 that can include the comparator circuit 122. The comparator circuit 122 can include a comparator input node 210, a reference signal input node 212, a first output node 214, and a second output node 216. The comparator circuit 122 can include multiple different circuit stages provided in series. For example, the comparator circuit 122 can include a high-voltage tolerant input stage 206, one or more gain stages, such as a first gain stage 202 through an nth gain stage 208, and an output stage 204. In an example, the first gain stage 202 can include a compare stage, or the input stage 206 can be configured to perform a comparison function.

In an example, the input stage 206 can be configured to receive information from the DUT node 132 from the DUT 124, such as via the loaded signal path 134, using the comparator input node 210. The input stage 206 can receive the comparator reference signal 128 Vth using the reference signal input node 212. Generally, the input stage 206 is configured to perform a signal comparison operation to determine which of the respective signals at the comparator input node 210 and the reference signal input node 212 has a greater or lesser signal amplitude characteristic, such as at a particular or specified time. A comparison result or output of the input stage 206 can be provided to the first gain stage 202. In an example, the comparison result includes a differential signal or logic signal, that is, a signal having two signal components.

In an example, the input stage 206 includes a differential amplifier that amplifies a differential voltage received at the comparator input node 210 and the reference signal input node 212, and suppresses common-mode signal components. Various other input stage 206 circuits can be used. The first gain stage 202 can include various gain or amplifier circuitry. Multiple gain stage instances can be provided in series, such that each gain stage further amplifies or buffers an output of a preceding gain stage. In the example of FIG. 2, the first gain stage 202 provides a first gain stage output signal to one or more intermediate gain stages that, in turn, provide a gain stage output using a last or nth gain stage 208. The nth gain stage 208 can be configured to provide an output signal into a relatively high input impedance receiver in the output stage 204.

In an example, the output stage 204 provides the differential comparator output signal 130 that includes first and second signal components Q and Qb at the first output node 214 and second output node 216, respectively. That is, the comparator stage output signal components can be used to provide a digital output signal indicative of a magnitude relationship between the input signals received at the comparator input node 210 and the reference signal input node 212.

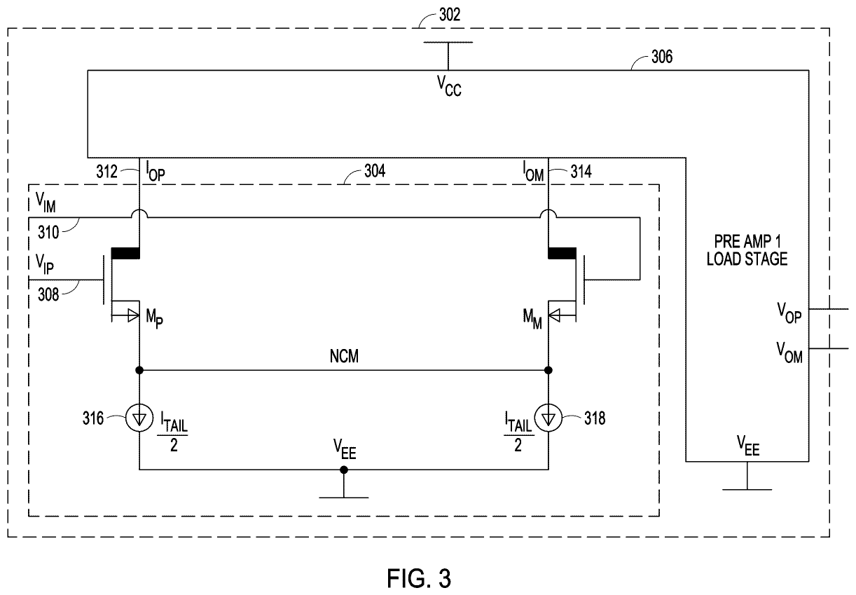

FIG. 3 illustrates generally an example of a first amplification stage 302. The first amplification stage 302 can include a first transconductance circuit 304 with multiple follower circuits. In the example of FIG. 3, the first transconductance circuit 304 includes a pair of source-follower circuits arranged as a differential pair. In an example, the first amplification stage 302 comprises a comparator or an amplifier, such as can include the input stage 206 of the comparator example 200 of FIG. 2. The first amplification stage 302 can be a first preamplifier stage and may be followed up by one or more other gain stages. In the example of FIG. 3, the first amplification stage 302 can include a load circuit 306, which in turn can provide an output to a subsequent gain stage or output stage.

The example of FIG. 3 shows a first input transistor M_{P} comprising a first portion of the first transconductance circuit 304 and a second input transistor MM comprising a second portion of the first transconductance circuit 304. In an example, the input transistors M_{P} and M_{M} comprise a differential pair circuit. Each of the input transistors M_{P} and M_{M} can include a respective high-voltage transistor (e.g., an LDMOS transistor). A common-mode voltage range of the differential pair can be equal to the LDMOS drain-source (DS) breakdown voltage (BV), or BVDS (e.g., 24 V or more). The differential input voltage range, however, can be approximately equal to a gate-to-source breakdown voltage plus a gate-to-source voltage, or VGS (e.g., 6 V).

In the first transconductance circuit 304, one terminal of the first input transistor M_{P} (e.g., the gate terminal of the transistor M_{P}) is coupled to a first input 308 and the first input transistor M_{P} receives a first input voltage V_{IP}. One terminal of the second input transistor M_{M} (e.g., the gate terminal of the transistor M_{M}) is coupled to a second input 310 and the second input transistor M_{M} receives a second input voltage V_{IM}. A second terminal of the first input transistor M_{P} (e.g., the drain terminal of the transistor M_{P}) is coupled to a first output 312 to provide a first output current I_{OP}, and a second terminal of the second input transistor M_{M} (e.g., the drain terminal of the transistor M_{M}) is coupled to a second output 314 to provide a second output current IoM. A third terminal of the first input transistor M_{P} (e.g., the source terminal of the transistor M_{P}) is coupled to a third terminal of the second input transistor M_{M} (e.g., the source terminal of the transistor M_{M}), e.g., via an intermediate node NCM. For each of transistors M_{P} and M_{M}, the source terminal of the transistor can be coupled to the back gate terminal of the transistor.

In an example, the first transconductance circuit 304 can include a tail current source, such as a first current source 316 and a second current source 318. The first current source 316 can be coupled to the source terminal of the first input transistor M_{P}, and the second current source 318 can be coupled to the source terminal of the second input transistor M_{M}. Together, the first current source 316 and the second current source 318 provide a total tail current I_{Tail} for the differential pair of the input transistors M_{P} and M_{M} of the first transconductance circuit 304. In an example, each of the first current source 316 and the second current source 318 provides a tail current I_{Tail}/2.

In some examples, the first transconductance circuit 304 comprises a portion of a comparator circuit, such as can be included in the comparator example 200. In this case, V_{IP} and V_{IM} can be the inputs to the comparator. The inputs can be provided or driven by an outside source, such as a DUT. The first transconductance circuit 304 can thus be configured to evaluate a difference between the voltage levels of the inputs V_{IP} and V_{IM} and generate an output current that represents whether the difference is positive or negative (e.g., to generate a logic 1 or logic 0 output indicative of whether the difference between the voltage levels of the inputs V_{IP} and V_{IM} is positive or negative). For example, when the difference I_{OP}−I_{OM} is positive then the difference V_{IP}−V_{IM} is positive, and when the difference I_{OP}−I_{OM} is negative then the difference V_{IP}−V_{IM} is negative. A magnitude of the difference between I_{OP} and I_{OM} can be a function of the magnitude difference between V_{IP} and V_{IM}.

In an example, the first transconductance circuit 304 comprises an amplifier, such as can be used in a feedback circuit. Such an example of the first transconductance circuit 304 can be configured to make the inputs V_{IP} and V_{IM} substantially equal by changing the outputs I_{OP} and I_{OM}, which outputs may then be coupled to the amplifier input through a feedback path.

A problem with the first transconductance circuit 304 may arise because the voltage at the NCM node is set by the one of the input transistors M_{P} and My that has the largest input voltage at its gate. When the differential pair of the input transistors M_{P} and M_{M} completely switches the tail current IT to a particular one of the first output 312 and the second output 314, the turned-off input transistor (i.e., the one of the input transistors M_{P} and M_{M} that has the lowest input signal at its gate terminal) can experience a gate breakdown at its source terminal boundary. For example, when the first transconductance circuit 304 is used in a comparator (e.g., a high-voltage comparator), the difference between V_{IP} and V_{IM} can exceed the gate oxide reliability voltage rating of the input transistors M_{P} and M_{M}. When the first transconductance circuit 304 is used in an amplifier, and if the amplifier input signal range is larger than the breakdown ratings of the input transistors M_{P} and M_{M}, then the amplifier may have the same reliability problem as a high-voltage comparator. During steady-state, such as when the amplifier settles to its final output level or waveform, the two inputs V_{IP} and V_{IM} would be substantially equal and would not have a reliability problem, but the inputs V_{IP} and V_{IM} can be significantly different at the beginning of the settling, which can create reliability issues for the amplifier. Hence, the differential pair-based first transconductance circuit 304 can be insufficient or unreliable for high-voltage applications where differential input voltage range exceeds a limit for device gate oxide reliability.

FIG. 4 illustrates generally an example of a second transconductance circuit 404 with a differential pair included in a second amplification stage 402. In an example, the second amplification stage 402 comprises a comparator or an amplifier, such as can comprise the input stage 206 of the comparator example 200. The second amplification stage 402 can be a first preamplifier stage and can be followed by one or more other gain stages.

The example of FIG. 4 shows the differential pair of input transistors M_{P} and M_{M}, such as comprising respective follower circuits, and each of the input transistors can include a high-voltage transistor (e.g., an LDMOS transistor). A common-mode voltage range of the input differential pair is equal to the LDMOS BVDS, e.g., 24 volts (V). The differential input voltage range, however, can be approximately equal to a gate-to-source breakdown voltage plus a gate-to-source voltage (VGS), e.g., about 6 V.

In the second transconductance circuit 404, as similarly provided for the first transconductance circuit 304, one terminal of the first input transistor M_{P} (e.g., the gate terminal of the transistor M_{P}) is coupled to the first input 308 and the first input transistor M_{P} receives a first input voltage V_{IP}. One terminal of the second input transistor M_{M} (e.g., the gate terminal of the transistor M_{M}) is coupled to the second input 310 and the second input transistor M_{M} receives a second input voltage V_{IM}. A second terminal of the first input transistor M_{P} (e.g., the drain terminal of the transistor M_{P}) is coupled to the first output 312 to provide a first output current I_{OP}, and a second terminal of the second input transistor M_{M} (e.g., the drain terminal of the transistor M_{M}) is coupled to the second output 314 to provide a second output current IoM.

In contrast to the example of the first transconductance circuit 304 from FIG. 3, the second transconductance circuit 404 in FIG. 4 includes a degeneration stage circuit 420. The degeneration stage circuit 420 is configured to provide an adjustable-impedance signal path that decouples the first input transistor M_{P} and the second input transistor M_{M}. The degeneration stage circuit 420 includes a first degeneration transistor M_{DP} and a second degeneration transistor M_{DM}. The first and second degeneration transistors M_{DP} and M_{DM} can function as nonlinear degeneration resistors. That is, each of transistors M_{DP} and M_{DM} operates as a resistor between their drain and source terminals, where the value of the drain-source resistance is based on the voltage difference between the first and second input voltages. In some examples, the variation of the drain-source resistance may be a nonlinear function of the voltage difference between the first and second voltage inputs. Since transistors M_{DP} and M_{DM} operate like resistors, they are degenerating the input differential pair formed by the first and second input transistors, M_{P} and M_{M}. Consequently, transistors M_{DP} and M_{DM} are referred to herein as “degeneration transistors.”

In the example of FIG. 4, a third terminal of the first input transistor M_{P} (e.g., the source terminal of the transistor M_{P}) is coupled to a third terminal of the first degeneration transistor M_{DP} (e.g., the source terminal of the first degeneration transistor M_{DP}, which source terminal is coupled to the back gate terminal of the first degeneration transistor M_{DP}). A third terminal of the second input transistor M_{M} (e.g., the source terminal of the transistor M_{M}) is coupled to a third terminal of the second degeneration transistor M_{DM} (e.g., the source terminal of the second degeneration transistor M_{DM}, which source terminal is coupled to the back gate terminal of the second degeneration transistor M_{DM}). The second terminal of the first degeneration transistor M_{DP} (e.g., the drain terminal of the first degeneration transistor M_{DP}) is coupled to the second terminal of the second degeneration transistor M_{DM} (e.g., the drain terminal of the second degeneration transistor M_{DM}) at the node NCM. The first terminal of the first degeneration transistor M_{DP} (e.g., the gate terminal of the first degeneration transistor M_{DP}) is coupled to the first input 308 where the first degeneration transistor M_{DP} receives the first input voltage V_{IP}, while the first terminal of the second degeneration transistor M_{DM} (e.g., the gate terminal of the degeneration transistor M_{DM}) is coupled to the second input 310 and the second degeneration transistor M_{DM} receives the second input voltage V_{IM}.

In operation of the second transconductance circuit 404, each of the first input transistor M_{P} and the second input transistor M_{M} can operate in a saturation region. The first degeneration transistor M_{DP} and the second degeneration transistor M_{DM} may be configured to operate either in a linear (triode) region or in a saturation region, and when one of the degeneration transistors M_{DP} and M_{DM} enters the saturation region, the other degeneration transistor can continue to operate in the linear region.

During operation of the second transconductance circuit 404, a degeneration resistance provided at the source terminal of the first degeneration transistor M_{DP} (e.g., the node NCMP shown in FIG. 4) and a degeneration resistance at the source terminal of the second degeneration transistor M_{DM} (e.g., the node NCMM) may be symmetric with respect to the input signal difference between V_{IP} and V_{IM}, or ΔV_{I}. That is, the resistance between the nodes NCMP and NCMM can change in accordance with changes in the applied input signal difference V_{IP}−V_{IM}. The value of this resistance can correspondingly change a value of the transconductance GM, where the change is symmetric in that G_{M}(V_{IP}−V_{IM})=G_{M}(V_{IM}−V_{IP}). Hence, the second transconductance circuit 404 can produce the same output currents I_{OP} and I_{OM} if a voltage difference of 100 mV or a voltage difference of −100 mV is applied at the inputs V_{IP} and V_{IM}.

In an example, a total degeneration resistance between the nodes NCMP and NCMM may be smallest when the first input voltage V_{IP} is substantially equal to the second input voltage V_{IM}. Furthermore, the equivalent resistance between the source terminal of the first degeneration transistor M_{DP} and the source terminal of the second degeneration transistor M_{DM} may increase as an absolute value (or magnitude) of a difference between the input voltages V_{IP} and V_{IM} increases. When the degeneration transistor whose gate terminal is coupled to the lowest input voltage (which could be either the first or second degeneration transistor M_{DP} or M_{DM}) enters into the saturation region, the positive and negative signal-handling portions of the second transconductance circuit 404 become effectively isolated from each other. Hence, the example input stage can tolerate a wide range of input differential voltages without requiring other protection devices.

Turning to the aspect ratios of various transistors included in the transconductance circuit, an aspect ratio (Aₓ) of a FET refers to a ratio of a channel width (wₓ) to a channel length (lₓ) of the FET. In some embodiments of a transconductance circuit, a ratio of an aspect ratio of the first degeneration transistor M_{DP} to an aspect ratio of the first input transistor M_{P} may be substantially equal to a ratio of an aspect ratio of the second degeneration transistor M_{DM} to an aspect ratio of the second input transistor M_{M}. In some embodiments, the aspect ratio of the first input transistor M_{P} may be substantially equal to the aspect ratio of the second input transistor M_{M}, or, equivalently, the aspect ratio of the first degeneration transistor M_{DP} may be substantially equal to the aspect ratio of the second degeneration transistor M_{DM}. For example, the aspect ratio of each of the first and second input transistors M_{P}, M_{M} may be about 1, while the aspect ratio of each of the first and second degeneration transistors M_{DP}, M_{DM} may be about N, where N is any positive real number. However, in other embodiments, these aspect ratios may be different, as long as the ratio of the aspect ratios of the first degeneration and input transistors M_{DP}, M_{P} is substantially equal to the ratio of the aspect ratios of the second degeneration and input transistors M_{DM}, M_{M}.

In the example of FIG. 4, the first and second degeneration transistors M_{DP} and M_{DM} reduce the equivalent transconductance G_{M} of the differential pair of the first and second input transistors M_{P} and M_{M}. It can be shown that the equivalent transconductance G_{M} at ΔV_{I}=0 may be reduced by N/(1+N). Hence, the equivalent transconductance G_{M} may drop to 80% of its value compared to the zero-degeneration case at the same power level when N=4.

When one of the first and second degeneration transistors M_{DP} and M_{DM} enters the saturation region, the drain current of the corresponding input transistor reaches its minimum level and is substantially equal to I_{Tail}/2*(N+1). The remaining of the respective input side tail current may then be conveyed to the complementary half input side through the degeneration transistor operating in the saturation region. Under this condition, the ratio of the output currents can be substantially equal to 2N+1. If desired, these values can be arbitrarily set by properly choosing the ratio of the input and degeneration transistor aspect ratios, i.e., by choosing N.

In some examples, high small-signal gain and small input signal difference for total tail current switching goals may favor a relatively large N value, whereas reduced large signal overdrive and reduced NCMP/NCMM node capacitance-related delay variation goals may favor a relatively small N value. The exact value of N used for the transistors in the second transconductance circuit 404 can be determined, for example, using simulation. It can be shown that, in some implementations, when one of the first and second degeneration transistors M_{DP} and M_{DM} enters into the saturation region, the other degeneration transistor stays in the linear operation region if N is chosen larger than or equal to about 1.5. The large voltage drop between NCMP and NCMM nodes may appear mainly across the drain source terminal of the degeneration transistor operating in the saturation region.

The second transconductance circuit 404 is thus substantially symmetric with respect to the input terminals and, therefore, can process both single-ended and differential input signals. By including the first and second degeneration transistors M_{DP} and M_{DM}, the second transconductance circuit 404 can operate up to the BVDS of the transistors included therein without reliability problems and in absence of additional protection mechanisms.

The present inventors have recognized, however, that while the second transconductance circuit 404 provides high Common Mode and Differential Mode voltage tolerance, it exhibits relatively low gain (transconductance) and low bandwidth. High gain, for example, generally requires use of physically large implementations (e.g., N>4) of the first and second degeneration transistors M_{DP} and M_{DM}, which in turn capacitively loads the first input 308 and the second input 310, respectively, and reduces bandwidth of the circuit. Conversely, high bandwidth generally requires use of physically small implementations of the first and second degeneration transistors M_{DP} and M_{DM}, which would reduce gain of the circuit. Thus, the circuit may not simultaneously achieve high gain and high bandwidth, which is undesirable for an ideal input stage. The present inventors have recognized that a solution to these and other problems can include or use a bias generator circuit to control operation of the first and second degeneration transistors M_{DP} and M_{DM}, and thereby more closely approximate behavior of an ideal input stage.

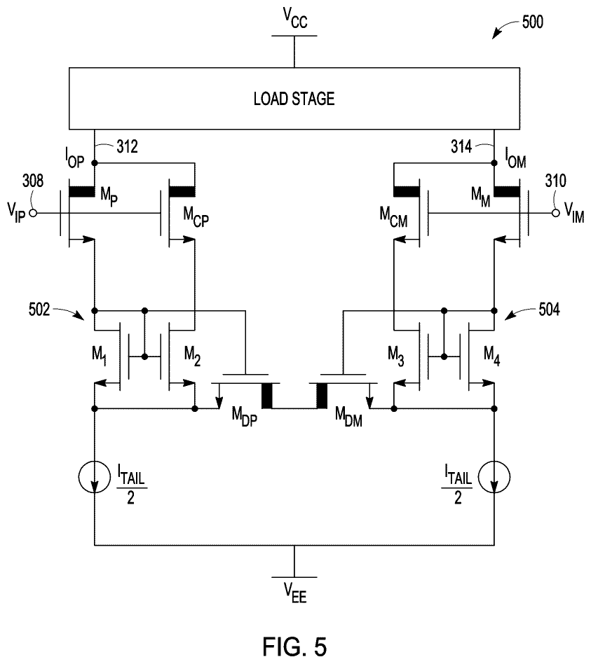

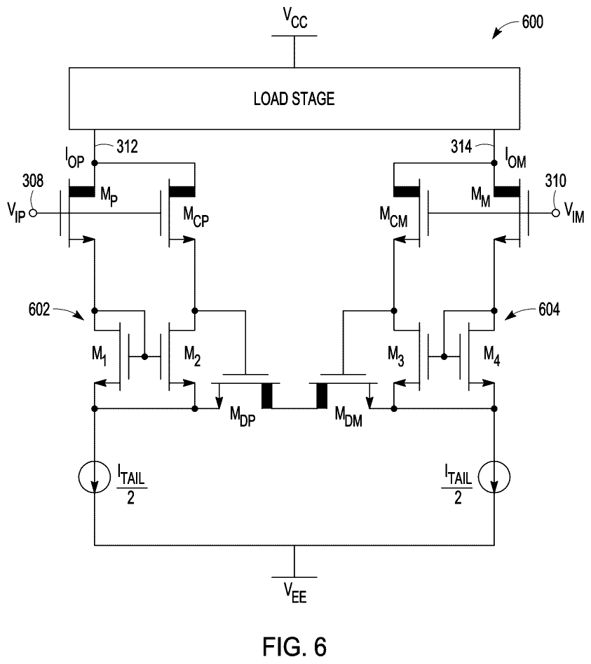

FIG. 5 and FIG. 6 illustrate generally examples of transconductance stages that use LDMOS devices for input and degeneration. The example stages are each symmetrical and exhibit CM and DM voltage tolerance that is limited by, e.g., a drain terminal breakdown voltage of the LDMOS devices. Each of these transconductance stage examples leverages current mirrors, comprising low-voltage devices, in biasing circuits for the higher-voltage LDMOS degeneration devices.

FIG. 5 illustrates generally a first example transconductance stage 500. In an example, the first example transconductance stage 500 comprises a comparator or an amplifier, such as can comprise the input stage 206 of the comparator example 200.

The example of FIG. 5 shows the differential pair of input transistors M_{P} and M_{M}, and each of the input transistors can include a high-voltage transistor (e.g., an LDMOS transistor). In the first example transconductance stage 500, as similarly provided in the first transconductance circuit 304 and the second transconductance circuit 404, one terminal of the first input transistor M_{P} (e.g., the gate terminal of the transistor M_{P}) is coupled to the first input 308 and the first input transistor M_{P} receives a first input voltage V_{IP}. One terminal of the second input transistor M_{M} (e.g., the gate terminal of the transistor M_{M}) is coupled to the second input 310 and the second input transistor M_{M} receives a second input voltage V_{IM}. A second terminal of the first input transistor M_{P} (e.g., the drain terminal of the transistor M_{P}) is coupled to the first output 312 to provide a first output current I_{OP}, and a second terminal of the second input transistor M_{M} (e.g., the drain terminal of the transistor M_{M}) is coupled to the second output 314 to provide a second output current I_{OM}.

In contrast to the examples of FIG. 3 and FIG. 4, the first example transconductance stage 500 includes a first bias circuit 502 and a second bias circuit 504 configured to control operation or biasing of the first and second degeneration transistors M_{DP} and M_{DM}, such as can comprise LDMOS devices. The LDMOS devices M_{DP} and M_{DN} can be used as degeneration transistors for high-voltage protection when a large differential signal is present at the first input 308 and the second input 310.

The first bias circuit 502 includes a current mirror that comprises low-voltage MOS devices M₁ and M₂ and a cascode transistor. The cascode transistor can include a LDMOS device M_{CP}. The second bias circuit 504 similarly includes a current mirror that comprises low-voltage MOS devices M₃ and M₄ and an LDMOS cascode transistor M_{CM}. Each of the current mirrors can have a mirroring ratio of K. In an example, the potential difference between supply voltages V_{CC} and V_{EE} can be up to several hundreds of volts. Therefore, the transistors M_{CP} and M_{CN} are used as high-voltage cascodes for the current mirror output devices M₂ and M₃ to protect these low-voltage devices of the respective current mirrors against drain to source breakdown when the input stage is subject to large differential input signals.

FIG. 6 illustrates generally a second example transconductance stage 600. The second example transconductance stage 600 includes a third bias circuit 602 and a fourth bias circuit 604 configured to control operation or biasing of the first and second degeneration transistors M_{DP} and M_{DM}. Each of the bias circuits includes a respective current mirror comprising low-voltage devices.

For example, the third bias circuit 602 includes a current mirror that comprises low-voltage MOS devices M₁ and M₂ and the LDMOS cascode transistor M_{CP}. The fourth bias circuit 604 similarly includes a current mirror that comprises low-voltage MOS devices M₃ and M₄ and an LDMOS cascode transistor M_{CM}. Each of the current mirrors can have a mirroring ratio of K. In an example, the transistors M_{CP} and M_{CN} are used as high-voltage cascodes for M₂ and M₃ to protect the low-voltage devices of the respective current mirrors against drain to source breakdown, where the potential difference between supply voltages V_{CC} and V_{EE} can be up to several hundreds of volts.

In the second example transconductance stage 600, the gate terminals of the degeneration transistors M_{DP} and M_{DN} are connected to respective source terminals of the LDMOS cascode devices M_{CP} and M_{CN}. This is in contrast with the first example transconductance stage 500 where the gate terminals of the degeneration transistors M_{DP} and M_{DN} are connected to the diode-connected, low-voltage devices M₁ and M₄, respectively. The second example transconductance stage 600 can be functionally identical to the first example transconductance stage 500 when the aspect ratio of M_{P} and M_{M} to M_{CP} and M_{CM}, respectively, is equal to the mirror ratio (K) of the low-voltage MOS devices M_{1/4} and M_{2/3}.

The first example transconductance stage 500 and the second example transconductance stage 600 leverage low-voltage current mirrors in their respective bias circuits for various reasons. First, the diode-connected transistors of the current mirrors (e.g., M₁ and M₄) provide respective bias voltage signals, or gate-to-source voltages, for the degeneration transistors (M_{DP} and M_{DN}). Accordingly, the gate terminals of the degeneration transistors are isolated from the transconductance stage inputs at the first input 308 and the second input 310. As a result, the total input capacitance at the input stage inputs is low, particularly relative to the example of the second transconductance circuit 404 from FIG. 4. In the first example transconductance stage 500 and second example transconductance stage 600, the de generation transistors operate either in the saturation or linear region, however, total effective degeneration impedance increases because M_{DP} and M_{DN} are in series with the diode-connected transistors M₁ and M₄ of the current mirrors.

Second, the current mirrors help compensate for reduction of the overall circuit transconductance due to the increased degeneration effect. By way of illustration, consider a small signal test voltage source is connected to the first input 308 at the gate terminal of the transistor M_{P}. The small signal current flowing through the transistor M_{P} will be mirrored, according to the mirror ratio K, by the low-voltage transistors (M₁ and M₂) and will be summed at the drain terminals of the input transistor M_{P} and the cascode transistor M_{CP}. When the mirroring ratio K is chosen to overcome the degeneration ratio of

$$1 + \frac{{gm}_{{M}_{P}}}{{gm}_{{M}_{1}}} ,$$

the overall transconductance can be increased.

It can be shown that an overall transconductance (Gₘ) of the first example transconductance stage 500 or second example transconductance stage 600 is given by

$${G}_{m} = ( K + 1 ) \cdot \frac{{gm}_{{M}_{P / M}}}{1 + {gm}_{{M}_{P / M}} \cdot ( \frac{1}{{gm}_{{M}_{1 / 4}}} + {rds}_{{M}_{DP / DM}} )}$$

where K is the mirror ratio between M_{1/4} and M_{2/3}, gm_{MP/M} and gm_{M1/4} are the transconductance of the input transistors M_{P/M} and mirror devices M_{1/4}, respectively, and rds_{MDP/DM} is the on-resistance of the degeneration transistors M_{DP/DM}. Various design trade-offs exist, however. For example, the overall transconductance Gₘ is proportional to the mirror ratio K. However, as the mirror ratio K increases, less drain-to-source current flows through transistors M_{1/4} of the current mirrors, which in turn lowers the gate-to-source voltages of these devices and thus increases rds_{M}_{_{DP/DM}}.

In an example, to minimize the impact of the degeneration due to current flow in transistors M_{1/4} of the current mirrors, a large aspect ratio for these transistors can be used. Increasing the aspect ratio of transistors M_{1/4} increases the transconductance gm_{M}_{_{1/4}} of the low-voltage mirror devices, however, for a given tail current I_{Tail} and mirror ratio K, the bias current of transistors M_{1/4} is constant. Increasing the aspect ratio of transistors M_{1/4} reduces their gate to source voltage, which in turn increases rds_{M}_{_{DP/DM}}. On the other hand, an aspect ratio of the degeneration transistors M_{DP/DM} can be increased at the expense of lowering rds_{M}_{_{DP/DM}} and occupying additional physical area.

In some examples, a threshold mismatch between the higher-voltage LDMOS and lower-voltage MOS devices may lead to insufficient gate-to-source voltage for the degeneration transistors M_{DP/DM} to fully turn on. If lower on-resistance rds_{M}_{_{DP/DM}} of the degeneration transistors M_{DP/DM} is desired, then a voltage source (V_{dc}) can be provided between the source terminal of the input transistor and the drain terminal of the diode-connected transistor in the current mirror of the bias circuit. In an example, the voltage source can include or use a resistor, a diode (e.g., a Schottky diode can be used, if available) or a diode-connected low-voltage MOS device, such as can be provided in series with the mirror transistors.

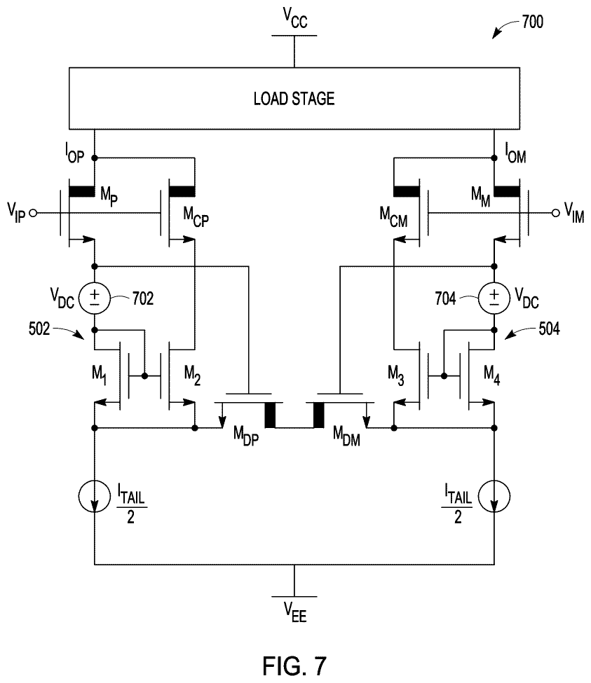

FIG. 7 illustrates generally a third example transconductance stage 700 that includes voltage sources configured to apply respective voltage signals at the gate terminals of the degeneration transistors M_{DP} and M_{DM}. In an example, the third example transconductance stage 700 includes an instance of the first example transconductance stage 500 with the first bias circuit 502 and the second bias circuit 504, however, the third example transconductance stage 700 further includes a first voltage source 702 at the source terminal of the first input transistor M_{P} and a second voltage source 704 at the source terminal of the second input transistor M_{M}.

In an example, voltage signals from the first voltage source 702 and the second voltage source 704 can be used to increase the gate-to-source voltages applied at the gate terminals of the degeneration transistors M_{DP} and M_{DM}. One potential drawback of the third example transconductance stage 700 is that overall headroom is reduced due to the diode-connected low-voltage devices and the voltage sources that are used to overcome the threshold voltage mismatch. However, the headroom reduction is generally inconsequential relative to the available supply range (e.g., V_{EE} to V_{CC}) that can be up to several hundreds of volts.

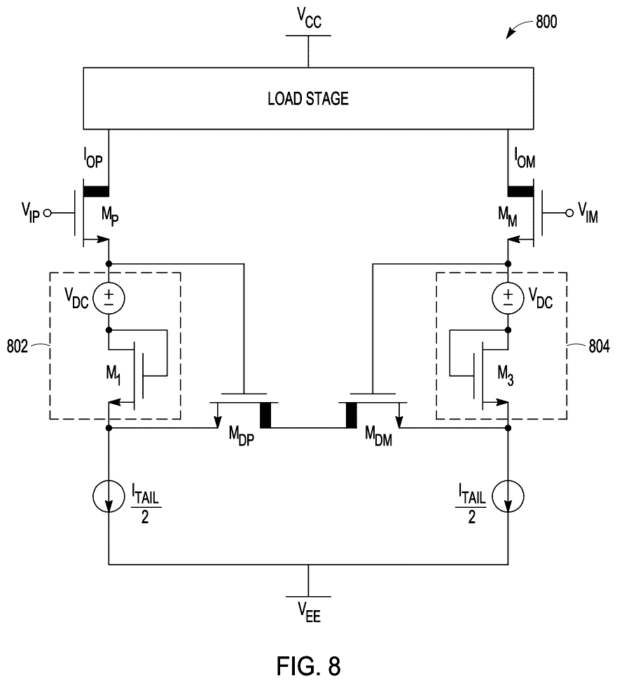

FIG. 8 illustrates generally a fourth example transconductance stage 800. The fourth example transconductance stage 800 does not include or use the same bias circuits with LDMOS cascode devices and low-voltage current mirrors to compensate for the transconductance losses due to degeneration effects, as in the first example transconductance stage 500, the second example transconductance stage 600, and the third example transconductance stage 700. Instead, in the fourth example transconductance stage 800, the gate terminals of the degeneration transistors M_{DP} and M_{DM} are controlled using a first isolation circuit 802 and a second isolation circuit 804, respectively.

The first isolation circuit 802 includes a low-voltage diode-connected transistor M₁ and optionally includes a series voltage source VDC connected to the source terminal of the first input transistor M_{P}. Similarly, the second isolation circuit 804 includes a low-voltage diode-connected transistor M₃ and optionally includes a series voltage source V_{DC} connected to the source terminal of the second input transistor M_{M}. At equilibrium, half of a bias current (I_{Tail}) flows through each of the input transistors M_{P} and M_{M} and the diode-connected transistors M₁ and M₃. Unlike the first example transconductance stage 500 and the second example transconductance stage 600, the fourth example transconductance stage 800 does not divide the bias current between the input transistors M_{P} and M_{M} and corresponding LDMOS cascode devices, and thus a larger portion of the bias current flows through the input transistors M_{P} and M_{M}.

In an example, each of the input transistors M_{P} and M_{M} can comprise a combination of multiple, parallel-connected LDMOS devices. Similarly, each of the diode-connected transistors M₁ and M₃ can comprise a combination of multiple, parallel-connected low-voltage devices. In this example and due to the parallel connection of multiple LDMOS devices in the input differential pair, the aspect ratio of the input devices can be larger relative to, for example, the input devices of the third example transconductance stage 700. As a result, the fourth example transconductance stage 800 can offer better performance in terms of flicker noise and offset relative to the third example transconductance stage 700.

The bias circuits and isolation circuits discussed herein for the various input stage examples provide improvements in both Common Mode (CM) and Differential Mode (DM) voltage tolerance. These circuits achieve the improvements by, for example, actively controlling gate voltages of the degeneration transistors M_{DP} and M_{DM} to maximize degeneration transistor Vgs. The circuits establish degeneration transistor Vgs at a maximum allowable voltage, thereby minimizing degeneration transistor linear region impedance and maximizing gain. Minimizing the linear region impedance enables the transistor size to be decreased, thereby increasing bandwidth while still maintaining sufficient gain. The circuits can also help avoid loading effects at the input nodes that could be caused by, for example, coupling the degeneration transistors to the inputs. The circuits discussed herein thus help optimize transconductance circuit function by allowing bandwidth and gain manipulation while providing superior gain bandwidth product.

In an example, the bias and isolation circuits help enable the degeneration transistors to transition smoothly between the linear and saturation regions of operation based on the differential input signals. When the inputs are substantially equal, the circuits maintain the degeneration transistors in the linear region, acting as low-impedance paths and allowing for high transconductance and high bandwidth. When the inputs are not equal, the circuits cause one of the degeneration transistors to enter the saturation region, effectively becoming a current source that holds off the differential voltage across its drain-gate junction. This allows the input stage to tolerate large differential input voltages without the risk of exceeding the voltage ratings of the transistors.

By decoupling the input signals from the direct control of the degeneration transistors, the bias and isolation circuits help reduce capacitive loading effects at the inputs, thereby providing superior gain bandwidth product relative to other solutions.

In summary, the bias and isolation circuits provide a dual function: they help optimize degeneration transistor Vgs characteristics while isolating control of the degeneration transistors from the input signals, and thereby help maximize gain and bandwidth performance of the transconductance circuit or input stage. This in combination with the inherent voltage-handling benefits of LDMOS devices results in a transconductance circuit with improved CM and DM voltage tolerance and improved gain bandwidth product, making it highly suitable for applications requiring robust performance across a wide range of operating conditions.

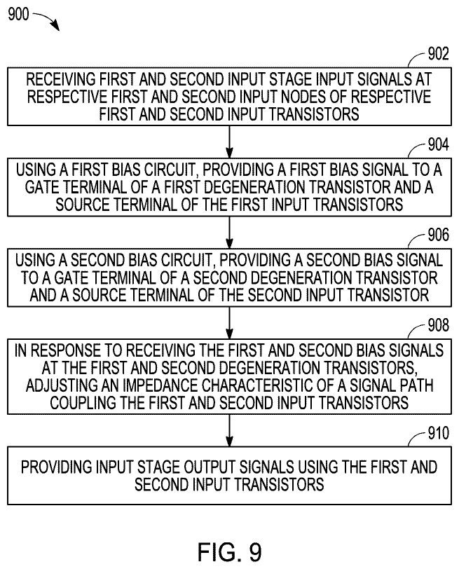

FIG. 9 illustrates generally an example of a first method 900 that includes operating an input stage with improved gain and bandwidth characteristics. In an example, the input stage can comprise a portion of a comparator circuit, such as can be used in a pin driver or other automated test equipment (ATE), among other things.

At operation 902, the first method 900 includes receiving first and second input stage input signals at respective first and second input nodes of respective first and second input transistors. In an example, the input transistors comprise respective LDMOS devices arranged as a differential pair.

At operation 904, the first method 900 includes using a first bias circuit, providing a first bias signal to a gate terminal of a first degeneration transistor and a source terminal of the first input transistor. At operation 906, the first method 900 includes using a second bias circuit, providing a second bias signal to a gate terminal of a second degeneration transistor and a source terminal of the second input transistor. In an example, the first and second degeneration transistors comprise respective LDMOS devices arranged in series. In an example, each of the bias circuits comprises a current mirror coupled between one of the input transistors and its corresponding degeneration transistor. The bias circuits can further comprise respective cascode transistors coupled to the output of the current mirror and to the output (e.g., drain terminal) of the corresponding input transistor. In an example, the first method 900 can include receiving the first and second input stage input signals at gate terminals of the cascode transistors. In various examples, gate terminals of the degeneration transistors can be driven by a signal at an input node of the current mirror or at an output node of the current mirror.

In an example, additionally or alternatively to using the first and second bias circuits, one or more isolation circuits can be provided to help isolate control of the degeneration transistors from the input transistors. The isolation circuits can include, for example, a voltage source configured to drive the degeneration transistors.

At operation 908, the first method 900 includes, in response to receiving the first and second bias signals at the first and second degeneration transistors, adjusting an impedance characteristic of a signal path coupling the first and second input transistors. In an example, the signal path includes the first and second degeneration transistors arranged in series. When the first and second bias signals exceed a threshold voltage value, the signal path coupling the first and second input transistors has a lower impedance characteristic, and when at least one of the first and second bias signals does not exceed the threshold voltage value, the signal path coupling the first and second input transistors has a higher impedance characteristic.

At operation 910, the first method 900 includes providing a first output signal of the input stage using a first output terminal of the first input transistor and providing a second output signal of the input stage using a second output terminal of the second input transistor.

Various embodiments of transconductance circuits with degeneration transistors as described herein may be implemented in any kind of system where conversion of voltage to current may be used. One example of such a system was shown in FIG. 2 where the transconductance circuit comprises part of an amplification stage, and can further include a load as illustrated in any of FIG. 3 through FIG. 8. The transconductance circuit can optionally be followed by one or more other gain stages. In some embodiments, the transconductance circuit can comprise a portion of a comparator or an amplifier.

In some examples, the transconductance circuit can be included in a radio system, e.g., in an RF transmitter of a cellular wireless communication system. In still other examples, the transconductance circuit can be used in variable gain-amplifiers, continuous-time filters, delta-sigma modulators, or data converters.

Moreover, various embodiments of transconductance circuits with degeneration transistors can be implemented in various electronic devices. Examples of the electronic devices can include, but are not limited to, electronic products, parts of electronic products such as integrated circuits, vehicular electronics such as automotive electronics, etc. Further, the electronic devices can include unfinished or other intermediate products.

Various aspects of the present disclosure can help provide a solution to the amplifier input stage gain and bandwidth-related problems identified herein, as set forth in the following Examples.

Example 1 is an input stage circuit comprising: a first input transistor configured to receive a first portion of a differential input signal at a first gate terminal and provide a first portion of an output signal at a first drain terminal of the first input transistor; a second input transistor configured to receive a second portion of the differential input signal at a second gate terminal and provide a second portion of the output signal at a second drain terminal of the second input transistor; and a degeneration stage circuit including a bias generator circuit, a first degeneration transistor and a second degeneration transistor, wherein the first and second degeneration transistors are coupled in series, wherein the bias generator circuit is configured to provide respective first and second bias signals to gate terminals of the first and second degeneration transistors to control an impedance of a signal path that couples source terminals of the first and second input transistors.

In Example 2, the subject matter of Example 1 optionally includes the bias generator circuit is configured to provide the first bias signal at a source terminal of the first input transistor, and provide the second bias signal at a source terminal of the second input transistor.

In Example 3, the subject matter of any one of Examples 1-2 optionally includes drain terminals of the first and second degeneration transistors are coupled at an intermediate node.

In Example 4, the subject matter of any one of Examples 1-3 optionally includes the bias generator circuit including a first current mirror coupled to the first input transistor, the first degeneration transistor, and a first cascode transistor; wherein the bias generator circuit includes a second current mirror coupled to the second input transistor, the second degeneration transistor, and a second cascode transistor; and wherein the first and second cascode transistors are coupled to the first and second drain terminals of the first and second input transistors, respectively.

In Example 5, the subject matter of Example 4 optionally includes, when the first and second portions of the differential input signal are substantially equal in magnitude, the first and second degeneration transistors operate in a linear region and provide a low-impedance signal path in the degeneration stage circuit.

In Example 6, the subject matter of any one of Examples 4-5 optionally includes, when the first and second portions of the differential input signal are not substantially equal in magnitude, the first degeneration transistor operates in a saturation region and the second degeneration transistor operates in a linear region to provide a high-impedance signal path in the degeneration stage circuit.

In Example 7, the subject matter of any one of Examples 1-6 optionally includes a first tail current source coupled to a drain terminal of the first degeneration transistor and a second tail current source coupled to a drain terminal of the second degeneration transistor.

In Example 8, the subject matter of Example 7 optionally includes respective tail current signals from the first and second tail current sources are configured to maintain operation of the first and second input transistors in their respective saturation regions.

Example 9 is a system comprising: a first portion of a transconductance circuit including: a first degeneration transistor; a first input transistor configured to receive a first portion of a differential input signal at a first input node and, in response, provide a first output current at a first output node, the first input transistor coupled to a gate terminal of the first degeneration transistor; and a first bias circuit configured to provide a first bias signal at the gate terminal of the first degeneration transistor; and a second portion of the transconductance circuit including: a second degeneration transistor coupled to the first degeneration transistor; a second input transistor configured to receive a second portion of the differential input signal at a second input node and, in response, provide a second output current at a second output node, the second input transistor coupled to a gate terminal of the second degeneration transistor; and a second bias circuit configured to provide a second bias signal at the gate terminal of the second degeneration transistor.

In Example 10, the subject matter of Example 9 optionally includes the first bias circuit comprises a voltage source configured to provide the first bias signal at the gate terminal of the first degeneration transistor and a source terminal of the first input transistor.

In Example 11, the subject matter of Example 10 optionally includes the first bias circuit comprises a diode, or a diode-connected transistor, coupled between the voltage source and a source terminal of the first degeneration transistor.

In Example 12, the subject matter of any one of Examples 9-11 optionally includes drain terminals of the first and second degeneration transistors are coupled at an intermediate node.

In Example 13, the subject matter of any one of Examples 9-12 optionally includes the first bias circuit comprises a current mirror coupled between gate and source terminals of the first degeneration transistor.

In Example 14, the subject matter of Example 13 optionally includes a source terminal of the first input transistor is coupled to the gate terminal of the first degeneration transistor.

In Example 15, the subject matter of any one of Examples 13-14 optionally includes the first and second input transistors and the first and second degeneration transistors comprise higher-voltage LDMOS transistors, and transistors comprising the current mirror of the first bias circuit comprise lower-voltage MOS transistors.

In Example 16, the subject matter of any one of Examples 13-15 optionally includes a first cascode transistor coupled between the first output node and the first bias circuit.

Example 17 is a method for controlling gain and bandwidth characteristics of an input stage circuit, the method comprising: receiving first and second input stage input signals at respective first and second input nodes of respective first and second input transistors; using a first bias circuit, providing a first bias signal to a gate terminal of a first degeneration transistor and a source terminal of the first input transistor; using a second bias circuit, providing a second bias signal to a gate terminal of a second degeneration transistor and a source terminal of the second input transistor; in response to receiving the first and second bias signals at the first and second degeneration transistors, adjusting an impedance characteristic of a signal path coupling the first and second input transistors; providing a first input stage output signal using a first output terminal of the first input transistor; and providing a second input stage output signal using a second output terminal of the second input transistor.

In Example 18, the subject matter of Example 17 optionally includes receiving the first and second input stage input signals at respective first and second cascode transistors, wherein the first cascode transistor is coupled between the first output terminal and the first bias circuit, and wherein the second cascode transistor is coupled between the second output terminal and the second bias circuit.

In Example 19, the subject matter of any one of Examples 17-18 optionally includes, when the first and second bias signals exceed a threshold voltage value, the signal path coupling the first and second input transistors has a lower impedance characteristic, and when at least one of the first and second bias signals does not exceed the threshold voltage value, the signal path coupling the first and second input transistors has a higher impedance characteristic.

In Example 20, the subject matter of any one of Examples 17-19 optionally includes receiving the first and second input stage input signals at the respective first and second input transistors including receiving the first and second input stage input signals at respective gate terminals of respective LDMOS devices.

Example 21 is an apparatus comprising means to implement of any of Examples 1-20.

Example 22 is a system to implement of any of Examples 1-20.

Example 23 is a method to implement of any of Examples 1-20.

Each of these non-limiting Examples can stand on its own, or can be combined in various permutations or combinations with one or more of the other Examples or features discussed elsewhere herein.

This detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. The present inventors contemplate examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.”

In the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods or circuit operations or circuit configuration instructions as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. An input stage circuit comprising:
a first input transistor configured to receive a first portion of a differential input signal at a first gate terminal and provide a first portion of an output signal at a first drain terminal of the first input transistor;
a second input transistor configured to receive a second portion of the differential input signal at a second gate terminal and provide a second portion of the output signal at a second drain terminal of the second input transistor; and
a degeneration stage circuit including a bias generator circuit, a first degeneration transistor and a second degeneration transistor, wherein the first and second degeneration transistors are coupled in series, wherein the bias generator circuit is configured to provide respective first and second bias signals to gate terminals of the first and second degeneration transistors to control an impedance of a signal path that couples source terminals of the first and second input transistors.

2. The input stage circuit of claim 1, wherein the bias generator circuit is configured to provide the first bias signal at a source terminal of the first input transistor, and provide the second bias signal at a source terminal of the second input transistor.

3. The input stage circuit of claim 1, wherein drain terminals of the first and second degeneration transistors are coupled at an intermediate node.

4. The input stage circuit of claim 1, wherein the bias generator circuit includes a first current mirror coupled to the first input transistor, the first degeneration transistor, and a first cascode transistor;
wherein the bias generator circuit includes a second current mirror coupled to the second input transistor, the second degeneration transistor, and a second cascode transistor; and
wherein the first and second cascode transistors are coupled to the first and second drain terminals of the first and second input transistors, respectively.

5. The input stage circuit of claim 4, wherein when the first and second portions of the differential input signal are substantially equal in magnitude, the first and second degeneration transistors operate in a linear region and provide a low-impedance signal path in the degeneration stage circuit.

6. The input stage circuit of claim 4, wherein when the first and second portions of the differential input signal are not substantially equal in magnitude, the first degeneration transistor operates in a saturation region and the second degeneration transistor operates in a linear region to provide a high-impedance signal path in the degeneration stage circuit.

7. The input stage circuit of claim 1, comprising a first tail current source coupled to a drain terminal of the first degeneration transistor and a second tail current source coupled to a drain terminal of the second degeneration transistor.

8. The input stage circuit of claim 7, wherein respective tail current signals from the first and second tail current sources are configured to maintain operation of the first and second input transistors in their respective saturation regions.

9. A system comprising:
a first portion of a transconductance circuit including:
a first degeneration transistor;
a first input transistor configured to receive a first portion of a differential input signal at a first input node and, in response, provide a first output current at a first output node, the first input transistor coupled to a gate terminal of the first degeneration transistor; and
a first bias circuit configured to provide a first bias signal at the gate terminal of the first degeneration transistor; and
a second portion of the transconductance circuit including:
a second degeneration transistor coupled to the first degeneration transistor;
a second input transistor configured to receive a second portion of the differential input signal at a second input node and, in response, provide a second output current at a second output node, the second input transistor coupled to a gate terminal of the second degeneration transistor; and
a second bias circuit configured to provide a second bias signal at the gate terminal of the second degeneration transistor.

10. The system of claim 9, wherein the first bias circuit comprises a voltage source configured to provide the first bias signal at the gate terminal of the first degeneration transistor and a source terminal of the first input transistor.

11. The system of claim 10, wherein the first bias circuit comprises a diode, or a diode-connected transistor, coupled between the voltage source and a source terminal of the first degeneration transistor.

12. The system of claim 9, wherein drain terminals of the first and second degeneration transistors are coupled at an intermediate node.

13. The system of claim 9, wherein the first bias circuit comprises a current mirror coupled between gate and source terminals of the first degeneration transistor.

14. The system of claim 13, wherein a source terminal of the first input transistor is coupled to the gate terminal of the first degeneration transistor.

15. The system of claim 13, wherein the first and second input transistors and the first and second degeneration transistors comprise higher-voltage LDMOS transistors, and wherein transistors comprising the current mirror of the first bias circuit comprise lower-voltage MOS transistors.

16. The system of claim 13, comprising a first cascode transistor coupled between the first output node and the first bias circuit.

17. A method for controlling gain and bandwidth characteristics of an input stage circuit, the method comprising:
receiving first and second input stage input signals at respective first and second input nodes of respective first and second input transistors;
using a first bias circuit, providing a first bias signal to a gate terminal of a first degeneration transistor and a source terminal of the first input transistor;
using a second bias circuit, providing a second bias signal to a gate terminal of a second degeneration transistor and a source terminal of the second input transistor;
in response to receiving the first and second bias signals at the first and second degeneration transistors, adjusting an impedance characteristic of a signal path coupling the first and second input transistors;
providing a first input stage output signal using a first output terminal of the first input transistor; and
providing a second input stage output signal using a second output terminal of the second input transistor.

18. The method of claim 17, comprising receiving the first and second input stage input signals at respective first and second cascode transistors, wherein the first cascode transistor is coupled between the first output terminal and the first bias circuit, and wherein the second cascode transistor is coupled between the second output terminal and the second bias circuit.

19. The method of claim 17, wherein when the first and second bias signals exceed a threshold voltage value, the signal path coupling the first and second input transistors has a lower impedance characteristic, and wherein when at least one of the first and second bias signals does not exceed the threshold voltage value, the signal path coupling the first and second input transistors has a higher impedance characteristic.

20. The method of claim 17, wherein receiving the first and second input stage input signals at the respective first and second input transistors includes receiving the first and second input stage input signals at respective gate terminals of respective LDMOS devices.
